(19) United States
(12) Patent Application Publication
(10) Pub. No.: US 2004/0000478 A1
(43) Pub. Date: Jan. 1, 2004

(54) Rotating hollow cathode magnetron

(76) Inventor: Charles S. Guenzer, Palo Alto, CA (US)

Correspondence Address: Applied Materials, Inc., Patent / Legal Dept., M/S 2061, P.O. Box 450 A, Santa Clara, CA, 95052, US

(21) Appl. No.: 10/180,646

(22) Filed: Jun. 26, 2002

(51) Int. Cl. C23C 14/35

(52) U.S. Cl. 204/298.18; 204/298.21; 204/298.22

(57) ABSTRACT

A hollow cathode sputtering target and associated magnetron. The target includes a tubular sidewall and a circular roof forming a cylindrical vault arranged about an axis. The sidewall is surrounded by a first set of magnets of a first magnetic polarity along the axis. A second set of magnets, disposed in back of the roof, and asymmetric and rotatable about the axis, includes an outer pole preferably of the first magnetic polarity surrounding an inner pole of the opposed magnetic polarity and of lesser total magnetic intensity. Optionally, the roof and sidewall are separate members having individual power supplies. Further optionally, the first set of magnets are asymmetric and rotatable with the second set of magnets about the axis.

### BACKGROUND OF THE INVENTION

1. Field of the Invention

The invention relates generally to sputtering of materials. In particular, the invention relates to the magnetron creating a magnetic field to enhance sputtering in a hollow cathode plasma sputter reactor.

2. Background Art

Sputtering, alternatively called physical vapor deposition (PVD), is the most prevalent method of depositing layers of metals and related materials in the fabrication of semiconductor integrated circuits. It has long been used to deposit metals such as aluminum and copper for horizontal electrical interconnections in the one or more wiring levels used in integrated circuits. More recently, the emphasis for advanced applications has shifted to depositing a metal or metal nitride into high aspect-ratio holes, such as via holes extending through inter-level dielectric layers separating two wiring levels. Sputtering has typically been used to fill aluminum metallization into the high aspect-ratio via hole. An even more challenging application of sputtering is to coat thin, nearly conformal layers of a metal or a metal nitride onto the sides and bottom of the via hole. With copper metallization, sputtering is often used to deposit thin conformal layers of a refractory nitride, such as TaN, and a copper seed layer into the high aspect-ratio via holes and thereafter filling copper into the remainder of the hole by electrochemical placing (ECP).

A high ionization fraction of the sputtered metal atoms has been recognized as facilitating sputtering into deep holes. An RF bias applied to the pedestal electrode supporting the wafer produces a negative DC self bias on the wafer. The negative voltage attracts the positively charged metal ions deeply within the hole in the wafer surface. The metal ionization fraction is increased by an increased plasma density of the sputtering working gas, which is typically argon. In one approach of increasing the plasma density, additional RF energy is inductively coupled into a high-density plasma (HDP) reactor to increase the plasma density.

On the other hand, some desire to continue to use more conventional diode sputter reactors in which the only significant power applied to create the plasma is the DC power applied to the target although RF power is used to bias the pedestal electrode. One approach, called self ionized plasma (SIP) sputtering uses a small but strong magnetron to create a high-density plasma in only one area of the target, thus providing a high plasma density adjacent the magnetron with only moderate power applied to the target. The small magnetron needs to azimuthally scanned about the back of the planar target to provide uniform sputtering. Fu et al. describes this approach in U.S. Pat. No. 6,306,265.

Two other approaches use complexly shaped targets and associated magnetrons to create a large, low-loss volume of plasma. The first approach, generally referred to as hollow-cathode sputtering, uses a target shaped to have a right cylindrical vault facing the wafer. Helmer et al. describe the general configuration in U.S. Pat. No. 5,482, 611. Lai et al. in U.S. Pat. No. 6,193,854 and Lai in U.S. Pat. No. 6,217,716 disclose that a sidewall magnetron in a hollow cathode will produce non-uniform sputtering and may even result in net deposition on portions of the cathode target. They describe a rotating roof magnetron including either a tubular magnet, two arc-shaped magnet assemblies of opposed magnetic polarities, or a heart-shaped magnetron having horizontal magnets arranged in a closed path perpendicular to the constituent magnets.

The second approach involving a complexly shaped target, generally referred to as SIP⁺ sputtering, uses a target shaped to have a circularly symmetric annular vault facing the wafer. Gopalraja et al. describe the general configuration in U.S. Pat. No. 6,277,249 and in U.S. patent application Ser. No. 09/703,601, filed Nov. 1, 2000.

Although each of the three approaches offers its own advantages, it is desired to provide alternative designs for high-performance sputtering reactors of great flexibility.

### SUMMARY OF THE INVENTION

A plasma sputtering reactor includes a hollow cathode target with a roof and a cylindrical sidewall forming a generally right cylindrical vault about a central axis and preferably a dual magnetron disposed in back of the roof and sidewall portions of the target.

In one aspect of the invention, a sidewall magnetron arranged in back of the target sidewall has a symmetric set of first magnets of a first magnetic polarity along the central axis, and a small roof magnetron is asymmetrically arranged in back of the roof and is rotatable about the central axis. The roof magnetron includes an outer pole of the first magnetic polarity and having a first total magnetic intensity and an inner pole of the opposed second magnetic polarity, surrounded by the outer pole, and having a second total magnetic intensity significantly smaller than the first total magnetic intensity. The polarities of the poles of the roof magnets may optionally be reversed. The outer pole of the roof magnet may be circular or triangular in shape or shaped like a racetrack although other shapes are possible.

In another aspect of the invention, the roof and sidewall portions of the target are separate members that may be isolated from each other by an electrically insulating gap. If the gap is free space, it is preferably smaller than a plasma dark space and the inner portion of the sidewall target adjacent the gap may be curved. Separate power supplies may be connected to the two target portions.

In a third aspect of the invention, the sidewall magnets may be asymmetrically arranged about the central axis and be rotatable about the central axis. The roof magnetron may be stationary or be rotated with the sidewall magnets.

The invention includes varying process conditions such that the portions of the target are subject to varying densities of plasma, thereby affecting the metal ionization fraction between steps or between different portions of the target.

### BRIEF DESCRIPTION OF THE DRAWINGS

FIG. 1 is cross-sectional view of a sputtering reactor of the invention including a hollow cathode and rotating magnetron.

FIG. 2 is a bottom plan view of a circularly symmetric roof magnetron.

FIG. 3 is a bottom plan view of a triangularly shaped roof magnetron.

FIG. 4 is a schematic cross-sectional view of the magnetic field distribution produced in a hollow cathode by a small roof magnetron and a sidewall magnetron.

FIG. 5 is a cross-sectional view of a second embodiment of a sputter reactor of the invention including a two-piece hollow cathode target and rotating magnetron.

FIG. 6 is a cross-sectional view of a third embodiment of the invention including separate roof and sidewall targets separated by a gap and separate selective power supplies for the two targets.

FIG. 7 is a cross-section view of a fourth embodiment of the invention including rotatable roof and sidewall magnetrons, both of which being asymmetric about the central axis.

### DETAILED DESCRIPTION OF THE PREFERRED EMBODIMENTS

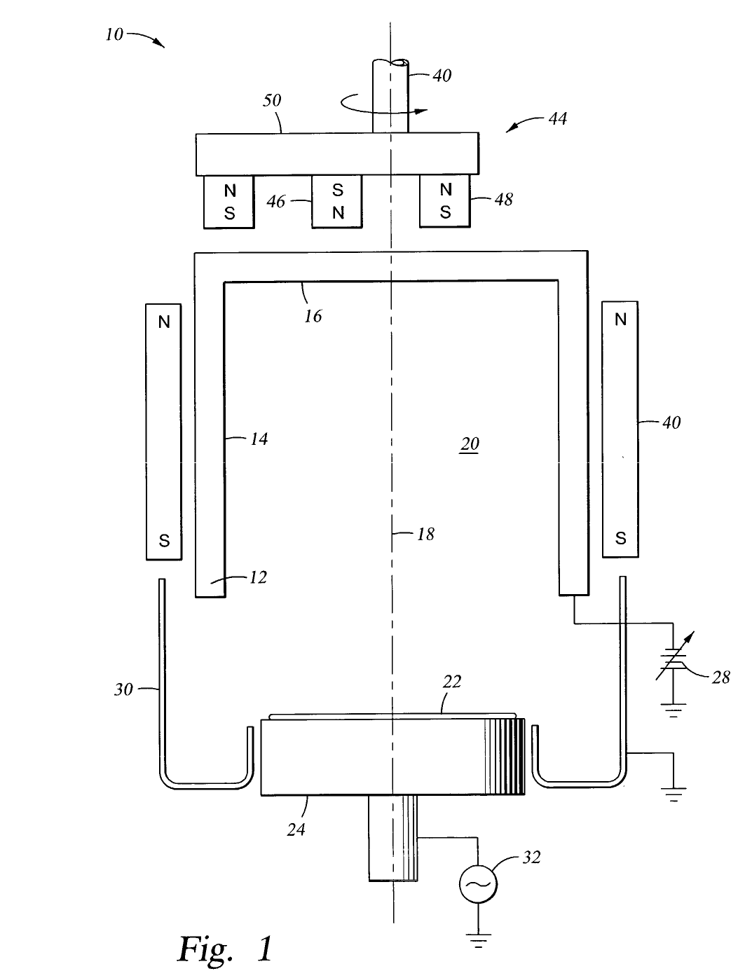

A first embodiment of the invention including a hollow cathode magnetron target assembly is illustrated in cross section in FIG. 1. A hollow cathode target 10 includes a tubular sidewall 14 with a right cylindrical inner face and a circular, disk-shaped roof 16 of the metal to be sputtered, for example, aluminum, copper, titanium, tantalum, or tungsten, symmetrically arranged about a central axis 18. The sidewall 14 and roof 16 define a generally right cylindrical vault 20 facing a wafer 22 to be sputter coated. The wafer is supported on a pedestal electrode 24 arranged about the central axis 18 and facing the roof 16 of the target. A variable DC power supply 28 negatively electrically biases the target 12 to about −600 VDC to discharge a working gas such as argon into a plasma. A grounded shield 30 acts as the anode in opposition to the target cathode and further protects the walls of the unillustrated vacuum chamber and sides of the pedestal electrode 24 from sputter deposition. An additional floating shield may be positioned closer to the target 12 to focus the plasma and metal ions. An RF power supply 32 is connected to the pedestal electrode 24 through an unillustrated capacitive coupling circuit and causes a negative DC self bias to develop on the pedestal electrode 24. The negative voltage is effective at accelerating metal ions towards the wafer 22 so that they more easily penetrate high aspect-ratio holes in the wafer 22. The remaining portions of the diode sputter reactor follow the general design in the above cited U.S. Pat. No. 6,306,265, incorporated herein by reference in its entirety.

The density of the plasma is increased by a dual-magnetron assembly. The resultant high-density plasma both increases the sputtering rate and increases the ionization fraction of the metal atoms sputtered from the target 12. The target sidewalls 14 are surrounded by a sidewall magnetron composed of a tubular magnet assembly 40 that has a first magnetic polarity along the central axis 18. The sidewall magnet assembly 40 may be a single tubular magnet, a stack of tubular magnets, or a two-dimensional tubular array of magnets. In this embodiment, the sidewall magnet assembly 40 is substantially symmetric about the central axis. A roof magnetron 44 is positioned behind the target roof 16. It includes an inner magnetic pole 46, in this embodiment of a second magnetic polarity opposite the first magnetic polarity, and an outer magnetic pole 48 of the opposed, first magnetic polarity. The outer pole 48 is formed in a closed band to surround the inner pole 46. A magnetic yoke support 50 supports and magnetically couple the inner and outer poles 46, 48 and is rotated about the central axis 18 by a drive shaft 52. Counterbalancing of the roof magnetron 44 about the rotation axis 18 is desirable. The roof magnetron 44 is non-symmetric about the central axis 18 and at any one time preferentially supplies magnetic flux to one azimuthal side of the target roof 16.

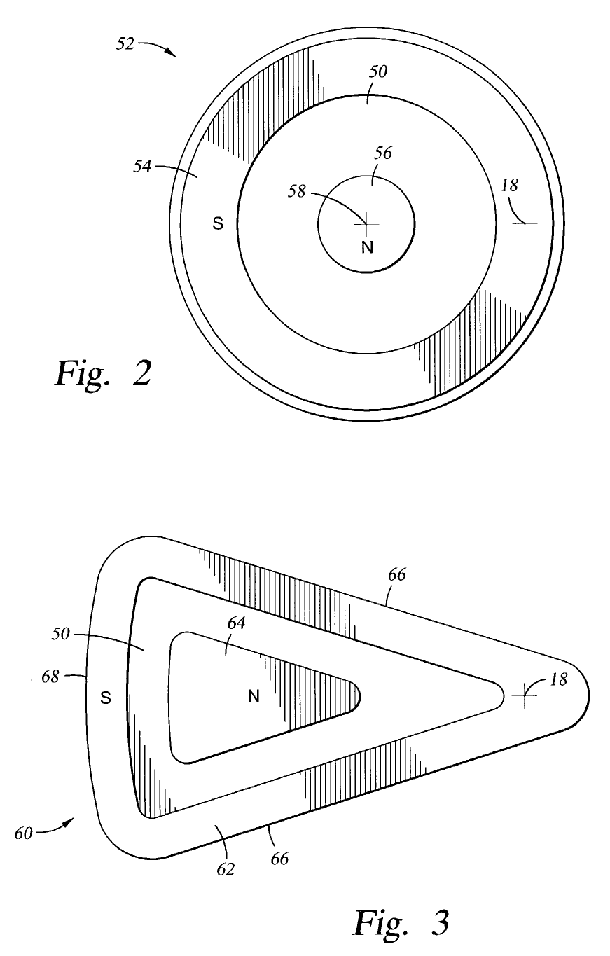

The roof magnetron 44 may be implemented in several forms. A circularly symmetric roof magnetron 52, shown in the bottom plan view of FIG. 2, includes an outer band-shaped pole face 54 of one magnet polarity surrounding a inner circular pole face 56 and separated from it by a substantially constant gap. The outer pole face 54 is typically a soft magnetic pole piece covering multiple cylindrical magnets arranged in a circle behind the outer pole face 54. The inner pole face 56 is typically a soft magnetic pole piece covering a single cylindrical magnet or multiple cylindrical magnets packed closely together and having magnetic polarities opposite that of the magnets associated with the outer pole face 54. The circular magnetron has a center 58 that is displaced from the central axis 18 of the reactor about which it rotates. The outer pole 54 may be positioned with its diameter extending between approximately the periphery of the target roof 16 to about the target center. As a result, the relatively small roof magnetron 52 sweeps across the entire circumference of the target roof. The roof magnetron 44 is preferably unbalanced with the total magnetic intensity of the pole of the outer pole face 54 being at least 150% of that of the pole of the inner pole face 56. The total magnetic intensity is the magnetic flux density integrated over the area of the respective pole face. In the case where the poles are constituted of one or more magnets of the same magnetic material covered by respective pole pieces, the ratio of the total magnetic intensities equals the ratio of the total cross sections of the magnets of the respective poles.

Suggestions have been made to form the inner pole face 56 in the shape of an annular band, for example, a tubular magnet or an equivalent circular arrangement of cylindrical magnets with an overlying annular pole piece. It is believed, however, that the maximum effect is obtained in conjunction with the hollow cathode target when the inner pole face 56 does not contain an included magnet-free aperture which can act as an electron sink from the plasma and increases the overall size of the roof magnetron.

Increased uniformity of roof sputtering may be achieved by a triangular roof magnetron 60, illustrated in bottom plan view in FIG. 3, including a triangularly band-shaped outer pole 62 surrounding a triangular inner pole 64 of the opposite magnetic polarity. The outer pole includes two straight portions 66 joined at an apex near the center of rotation 18 and an arc-shaped base 68 located near the somewhat similarly curved periphery of the target roof 16. The two straight portions 66 are inclined to each other by an apex angle that is preferably between 10 and 45°, more preferably between 20 and 35°. The triangular shape produces more magnetic flux at the target periphery than at its center to compensate for the higher magnetron speed at the periphery and thereby produces a more uniform time-averaged magnetic flux density over the entire target. Again, the triangular roof magnetron 60 is preferably unbalanced with a magnetically stronger outer pole 62.

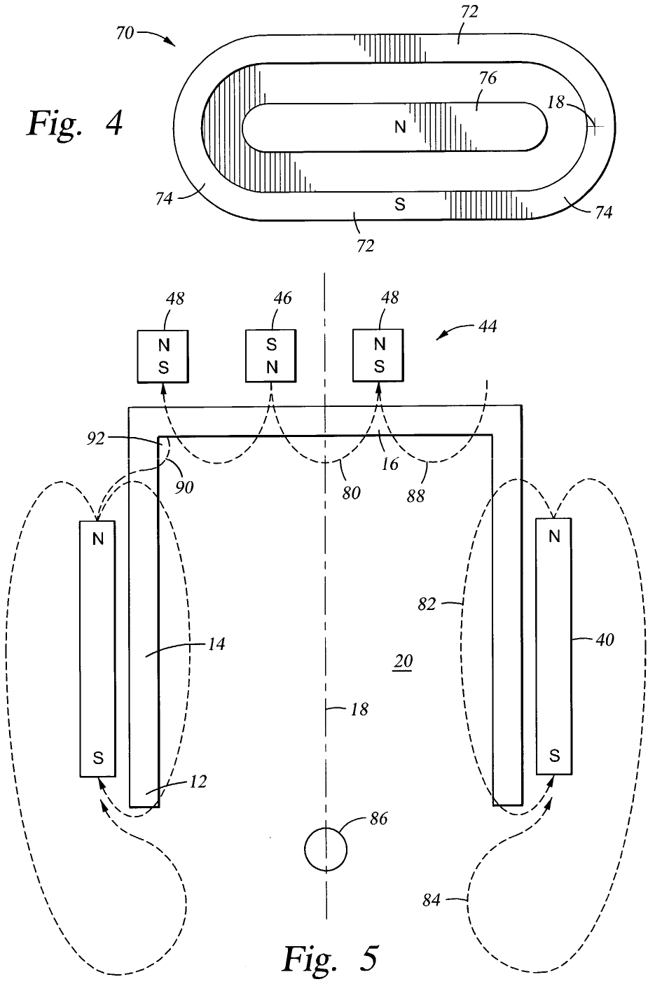

A racetrack-shaped magnetron 70, illustrated in the bottom plan view of FIG. 4, can provide a strong magnetic field most of the radial extent of the roof portion of the target. The racetrack magnetron includes an outer band-shaped pole of one magnetic polarity having two straight parallel portions 72 joined by two arc-shaped end portions 74, one of which generally overlies or is close to the rotation axis 18. The outer pole surrounds an inner pole 76 of the opposite magnetic polarity, which has a straight shape with rounded ends such that a nearly constant gap separates the inner pole 76 from the portions 72, 74 of the outer pole. Yet other target shapes are possible, as disclosed in the above cited U.S. Pat. No. 6,306,265.

The dual-magnetron assembly produces a relatively complex magnetic field distribution as generally illustrated in FIG. 5 although the precise distribution depends on the type of roof magnetron 44 and the location of the sidewall magnetron 40 along the target sidewall 14. The roof magnetron 44 produces a semi-toroidal magnetic field 80 extending in front of the target roof 16 in a closed path about the center of the roof magnetron 44 and having a substantial component parallel to the target roof 16 inside the vault 20. The parallel component is effective at trapping electrons and thus increasing the plasma density close to the target roof 16. The increased plasma density increases both the sputtering rate and the metal ionization fraction.

The sidewall magnet assembly 40 produces a magnetic field distribution that is mostly symmetric about the central axis 18 except near the roof magnetron 44. The sidewall magnetic distribution includes both an intra-vault component 82 extending generally parallel to the tubular target sidewall 14 and an extra-vault component 84 that originates from a first end towards and past the second end of the sidewall magnet assembly 40, then trends radially inwardly towards the central axis 18 before curving back to the second end of the magnet assembly 40. These two components 82, 84 result in a magnetic null 86 being formed near the open throat of the target vault 20.

Such a magnetic null 86 traps electrons and thus increases the plasma density. The intra-vault component 82 increases the plasma density near the target sidewall 14 though not as effectively as the semi-toroidal field 80 does near the target roof 16. The intra-vault component 82 guides metal ions from both the roof 16 and the sidewall 12 out through the target throat, and the high plasma density associated with the magnetic null 76 tends to ionize further metal atoms, both from the roof 16 and the sidewall 14. The negative DC self bias applied to the pedestal electrode 24 accelerates the metal ions to deep within the high aspect-ratio holes in the wafer 22.

Because of its unbalance, the roof magnetron 44 also produces a looping component 88 which extends from the front of the radially inner portions of the outer pole 48 and returns to its back in the regions of the roof 16 away from the sidewall magnet assembly 40, that is, on the right side as illustrated. The looping component 88 provides some magnetic confinement in that portion of the target roof 16 though less than does the semi-toroidal component 80 over the roof portions it overlies. In the portions of the target roof 16 and adjacent portions of the target sidewall 14 where the roof magnetron 44 is close to the sidewall magnetron 40, there is strong coupling between the two magnetrons 40, 40 largely arising from the unbalance of the roof magnetron 44. In the illustrated relative polarities of the sidewall and roof magnetrons 40, 44, the unbalance creates a coupling component 90 between the radially outer portions of the outer roof pole 48 and the adjacent portions of the sidewall magnet assembly 40. The coupling component 90 can be optimized to very strongly increase the density of the plasma in the target corner 92 near the coupling component 90. Of course, the high-density corner 92 rotates with the roof magnetron 44.

These effects are absent in the heart-shaped rotating roof magnetron disclosed by Lai in U.S. Pat. No. 6,217,716, which is a balanced magnetron composed of horseshoe magnets or equivalent magnet pairs arranged in a closed path and producing a magnetic field generally corresponding to one of the semi-toroidal components 80 but in a closed heart-shaped band. Lai's magnetron also extends over a larger area and includes a field-free inner area, which increases electron loss and thus decreases the plasma density relative to the magnetrons 52, 60, 70 of FIGS. 2-4, which have a small inner pole of continuous magnetic material. The very localized magnetic field distribution of Lai's heart-shaped magnetron effectively decouples his roof and sidewall magnetrons. Thus, Lai's magnetron is less amenable to some of the advantages of multiple modes of sputtering to be described later.

The semi-toroidal field 80 not only increases the sputtering of the target roof 16, but, because of the small size of the roof magnetron 44, its magnetic intensity can be made much greater than that of the sidewall magnet assembly 40 so that the two areas of the target may be operating in different sputtering modes allowing production of different ionization fractions. In some semiconductor fabrication applications, it may be desirable to operate with a relatively small metal ionization fraction. For example, a more isotropic deposition or a reduced high-energy component may be desired to accentuate wafer deposition by the metal neutrals over wafer sputtering by the metal ions. In other applications, a high ionization fraction may be desired. For example, metal ions may be accelerated by wafer bias deep into high aspect-ratio holes, thus permitting deep hole filling. Further, the strong forward energy distribution of the accelerated metal ions may be used to sputter barrier layers from the bottom of via holes while leaving them intact on the via sidewalls. It is particularly desired to permit such control between steps of a multi-step processing sequence in the same sputter reactor in which sputter etching of the wafer precedes sputter deposition. Such control can be accomplished at least in part by variations of the target power and chamber pressure. Of course, control of RF biasing of the pedestal electrode is also effective at control the metal ion energies.

Copper sputtering allows further control of sputtering modes based upon self-ionized plasmas utilizing high target power densities and high magnetic fields. In this type of sputtering, the metal ionization fraction is so high that some of the metal ions are attracted back to resputter the target. As a result, the argon pressure may be substantially reduced and in some cases reduced to zero. The substantially different magnetic fields associated with the sidewall and roof magnetrons may be optimized allow self-ionized sputtering of the roof but not of the sidewall. That is, with sufficiently reduced pressure, the roof may be sputtered while the sidewall is not. If the pressure is increased, the sidewall is sputtered. If the roof power is reduced, the sputtering of the roof changes to a more neutral sputtering.

With the magnetic polarities of the two magnetrons 40, 44 illustrated in FIG. 5, there is a very intense magnetic field in the portion of the upper corner 92 of the target 12 over which the roof magnetron 44 is then sweeping. This very intense field coupling the adjacent ends of the outer pole 48 and the sidewall magnet assembly 40 causes increased sputtering of the coupled corner area relative to the central area and the remainder of the corner of the target roof 16. This increase sputtering compensates for the deficient corner sputtering observed by Lai et al. On the other hand, corner sputtering can be de-emphasized by reversing the magnetic polarities of the poles 46, 48 of the roof magnetron 44 relative to the sidewall magnet assembly 40.

The uniformity of sputtering of the target roof 16 is further increased if the roof magnetron 44 is scanned in two dimensions, for example, with a planetary gear mechanism as disclosed by Hong et al. in U.S. patent application Ser. No. 10/152,494, filed May 21, 2002.

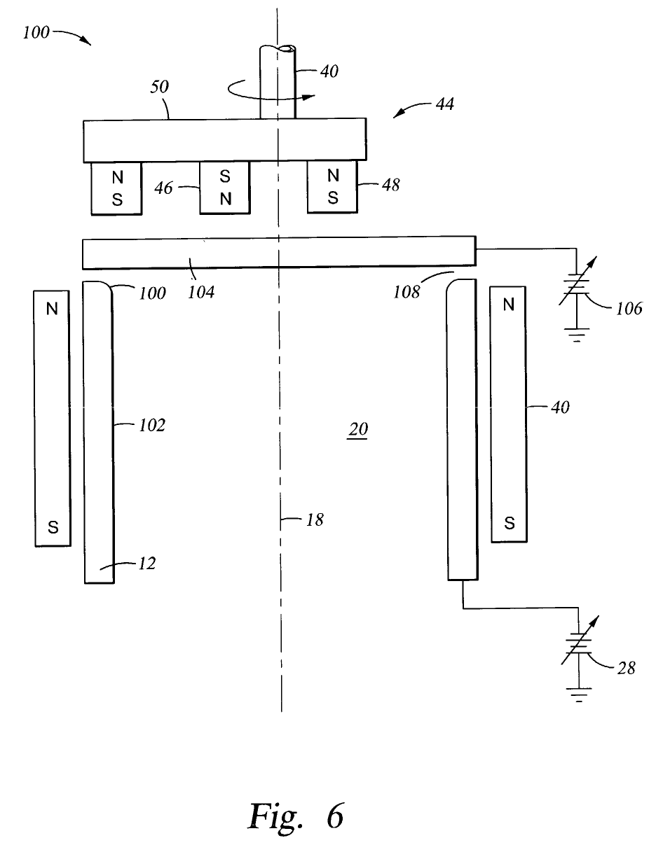

A further degree of control is accomplished by separating the powering of the target roof and sidewall. As illustrated in the cross-sectional view of FIG. 6, a sputter reactor 100 includes a hollow cathode target assembly composed of a tubular sidewall target 102 having a generally right cylindrical shape and a disc-shaped roof target 104. At least the surface portions of the two targets 102, 104 may be composed of substantially the same material so that the sputtered material deposited on the wafer 22 has effectively the same material regardless of which target 102, 104 it is sputtered from. It is possible, however, to vary the materials of the two targets 102, 104 for control of the composition of the sputter deposited layer. A separate, second variable DC power supply 106 negatively biases the roof target 104 with a selective amount of power relative to the power which the first DC power supply 28 applies to the sidewall target 102. A narrow electrically insulating gap 108 separates and electrically isolates the top of the sidewall target 102 from the periphery of the roof target 104. The gap 108 may be free space having a thickness less than the plasma dark space, the order of a millimeter or somewhat more, so that the plasma within the vault 20 cannot penetrate to the back of the two targets 102, 104. The top inside corner 110 of the sidewall target 102 may be rounded or beveled to minimize any localized discharge there. The degree of rounding as well as other detailed shaping of either target 102, 104, however, are small enough that the vault 20 is still best described as having a right cylindrical shape about the central axis 18. Alternatively, the gap 108 may be of variable thickness but be filled with a dielectric isolator. However, care must be taken to assure that the isolator is not sputtered or its sputter products not degrade the integrated circuit being formed. The separate selective powering of the sidewall and roof targets 102, 104 is not limited to hollow cathode reactor incorporating the unbalanced roof magnetron 44. Various other hollow cathode reactors would benefit from separate powering of the roof and sidewall portions of the hollow cathode target.

The same division between roof and sidewall target portions can be applied to the annularly vaulted target of Gopalraja et al, but requires a more complex mechanical design.

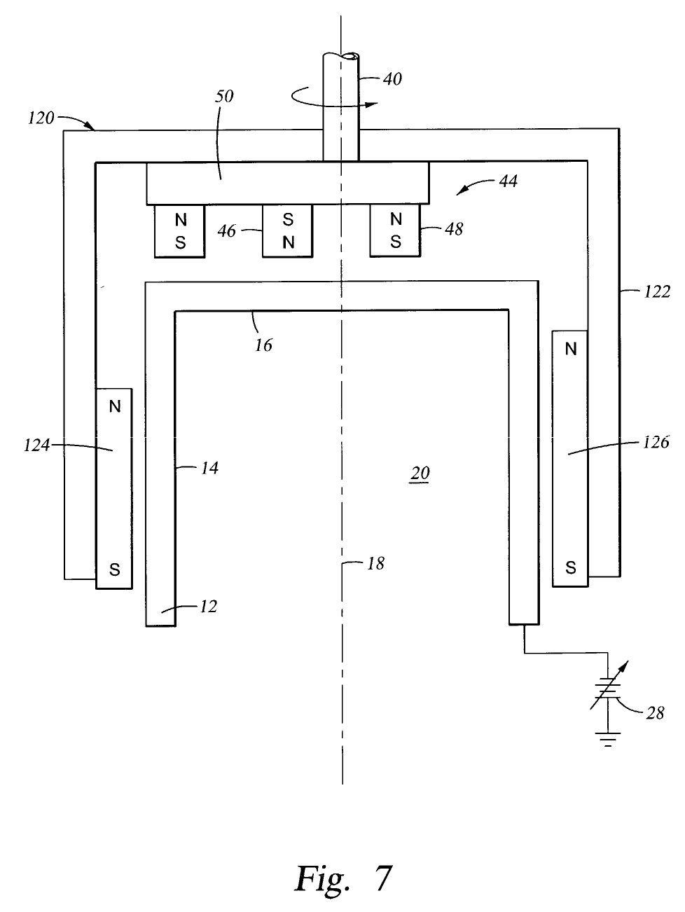

As illustrated in the cross-sectional view of FIG. 7, the design of the dual-magnetron assembly can be further optimized by azimuthally shaping the sidewall magnetron and rotating it with the roof magnetron 44. A sputter reactor system 120 includes a cup-shaped support 122 preferably composed of non-magnetic material and fixed to the rotary drive shaft 40. The magnetic yoke 50 of the roof magnetron 44 is supported by the top portion of the cup-shaped support 122. The sidewall magnetron includes magnet assemblies 124, 126 of different lengths or perhaps magnetic strengths attached to the side portions of the cup-shaped support 122 so that they rotate with the roof magnetron 44 about the central axis. The different magnet assemblies 124, 126, only two of which are illustrated, vary along the outer circumference of the cup-shaped support 122 so that the sidewall magnetron is asymmetric about the central axis 18. In one embodiment, the sidewall magnet assemblies 124 near the roof magnetron 44 are shorter so as to be more separated from the target roof 16 while those farther from the roof magnetron 44 extend along most of the target sidewall 14. The opposite relation of sizes may be applied to different effect. In other embodiments, the sidewall magnets may be lacking either near the roof magnetron 14 or away from it. In yet other embodiments, lower portions of the sidewall magnet assemblies may be stationary and uniform and separated from upper portions that are rotating and non-uniform. Yet further, a rotating asymmetric sidewall magnetron may be combined with a symnmetric and possibly stationary roof magnetron, that is, a roof magnetron that is circularly symmetric about the central axis 18.

The combination of roof and sidewall magnetrons provide additional flexibility in optimizing sputtering conditions for different applications. The unbalanced roof magnetron yields yet further flexibility with little increase in complexity.

1. A hollow cathode sputtering magnetron, comprising:
a target having a generally right cylindrical vault arranged about a central axis and including a cylindrical sidewall portion and a circular roof portion;
a sidewall magnet assembly comprising at least one sidewall magnet of a first magnetic polarity disposed radially outside of said cylindrical sidewall portion with respect to said central axis;
a roof magnet assembly disposed on a side of said roof portion opposite said vault, being asymmetric and rotatable about said central axis, and including
an inner pole of a second magnetic polarity along said central axis and having a first total magnetic intensity and
an outer pole of a third magnetic polarity opposite said second magnetic polarity surrounding said inner pole and having a second total magnetic intensity of at least 150% of said first total magnetic intensity.

2. The magnetron of claim 1, wherein said first and third magnetic polarity are a common magnetic polarity opposite said second magnetic polarity.

3. The magnetron of claim 1, wherein said inner and outer poles are substantially circularly symmetric.

4. The magnetron of claim 1, wherein said outer pole is triangularly shaped.

5. The magnetron of claim 4, wherein said outer pole comprises two straight sections inclined with respect to each other by an angle of between 10 and 45°.

6. The magnetron of claim 1, wherein said outer pole comprises two straight parallel portions separated by said inner pole.

7. The magnetron of claim 1, wherein said at least one sidewall magnet comprises a plurality of sidewall magnets asymmetrically arranged about said central axis and rotatable with said roof magnet assembly about said central axis.

8. The magnetron of claim 1, wherein said roof and sidewall portions are formed in an integral member.

9. The magnetron of claim 1, wherein said roof and sidewall portions are formed of separate members separated by a gap.

10. The magnetron of claim 9, wherein said gap is free space and has a thickness less than a plasma dark space.

11. A hollow cathode magnetron, comprising:
a roof target having an inner face that is substantially circularly symmetric out a central axis;
a first magnet assembly disposed in back of said roof target;
a first selective power supply connected to said roof target;
a sidewall target having at least one inner surface extending parallel to said central axis and being substantially circularly symmetric about said central axis and separated from said roof target by a gap and forming therewith a substantially circularly symmetrical vault;
a second magnet assembly disposed in back of said sidewall target; and
a second selective power supply connected to said sidewall target.

12. The magnetron of claim 11, wherein said sidewall target has two annular inner surfaces and said vault is annular.

13. The magnetron of claim 11, wherein said inner face of said roof target is substantially circular, said at least one inner surface of said sidewall target is one inner surface, and said vault is substantially right cylindrical.

14. The magnetron of claim 13, wherein said gap is less than a plasma dark space.

15. The magnetron of claim 13, wherein said first magnet assembly is rotatable about a back of said roof target.

16. The magnetron of claim 15, wherein said first magnet assembly comprises an inner pole of a first magnetic polarity along said central axis and an outer pole of a second magnetic polarity opposed to said first magnetic polarity and surrounding said inner pole.

17. The magnetron of claim 16, wherein a total magnetic intensity of said outer pole is at least 150% a total magnetic intensity of said inner pole.

18. The magnetron of claim 17, wherein said second magnet assembly comprises at least one magnetic of said second magnetic polarity.

19. A hollow cathode sputtering magnetron, comprising:
a target having a substantially right cylindrical vault arranged about a central axis and including a cylindrical sidewall portion and a circular roof portion;
a sidewall magnet assembly comprising a plurality of sidewall magnets asymmetrically arranged about said central axis, disposed radially outside of said tubular sidewall portion with respect to said central axis, and rotatable about said central axis;
a roof magnet assembly disposed on a side of said roof portion opposite said vault.

20. The magnetron of claim 19, wherein said roof magnet assembly is asymmetric about said central axis and rotatable with said sidewall magnet assembly about said central axis.

21. The magnetron of claim 20, wherein said roof magnet assembly comprises:
an inner pole of a second magnetic polarity along said central axis and having a first total magnetic intensity; and
an outer pole of a third magnetic polarity opposite said second magnetic polarity surrounding said inner pole and having a second total magnetic intensity of at least 150% of said first total magnetic intensity.

22. A hollow cathode target assembly having vault arranged about a central axis and comprising:
at least one sidewall target extending along said central axis and arranged about said central axis; and
a roof target extending perpendicularly to said central axis;
wherein said sidewall and roof targets are configured to be separated by at least one electrical insulating gap.

23. The target assembly of claim 22, wherein said at least one sidewall target comprises two generally cylindrically shaped sidewall targets and said roof target is annularly shaped.

24. The target assembly of claim 22, wherein said at least one sidewall target consists of one generally cylindrically shaped sidewall target and said roof target is generally disk-shaped.

25. The target assembly of claim 24, wherein said gap is free space and has a thickness less than a plasma dark space.

26. The target assembly of claim 25, wherein an inner corner of said sidewall target adjacent said gap is rounded.

27. The target assembly of claim 24, further comprising a dielectric material disposed within said gap.

28. The target assembly of claim 24, wherein said sidewall and roof targets have at least surface portions composed of substantially a same material to be sputter deposited.

29. The target assembly of claim 24, wherein said vault has a generally right cylindrical shape.

30. The target assembly of claim 24, further comprising a first magnet assembly positioned in back of said sidewall target from said vault.

31. The target assembly of claim 30, further comprising a second magnet assembly positioned in back of said roof target from said vault.

32. The target assembly of claim 22, further comprising:
a first selective power supply connected to said at least one sidewall target; and
a second selective power supply connected to said roof target.
